(19) United States
(12) Patent Application Publication
(10) Pub. No.: US 2026/0219350 A1
(43) Pub. Date: Jul. 30, 2026

(54) SYSTEM AND METHOD FOR CALIBRATING A DEVICE-UNDER-TEST INTERFACE

(71) Applicant: Advantest Corporation, Marunouchi, Chiyoda-ku, Tokyo (JP)

(72) Inventor: Shoji KOJIMA, Böblingen (DE)

(21) Appl. No.: 19/158,249

(22) PCT Filed: Feb. 24, 2023
(86) PCT No.: PCT/EP2023/054752

§ 371 Date: Aug. 20, 2025

(51) Int. Cl. G01R 35/00; G01R 31/28

(52) U.S. Cl. CPC G01R 35/005; G01R 31/2822

(57) ABSTRACT

Techniques for calibrating a device-under-test (DUT) interface includes a test head having a signal generator and a measuring unit configured to be connected by a first signal line, a DUT-unit having a loadboard with an input port and an output port connected by a second signal line, and a calculation unit. The signal generator is configured to generate a first calibration signal and transmit the first calibration signal to the measuring unit and the input port. The measuring unit is configured to measure a second calibration signal based on the first calibration signal received from the signal generator and a third calibration signal based on the first calibration signal received from the DUT-unit via the output port. The calculation unit is configured to calculate a main calibration signal based on the first, second, and third calibration signals and calibrate the DUT interface based on the main calibration signal.

The present invention relates to a system and a method for calibrating a device-under-test interface, in particular to a system and a method for calibrating a device-under-test interface regarding high-frequency/high-speed device tests exceeding 5 GHz.

Especially in high-speed device tests, in particular in high-speed device tests exceeding 5 GHZ, it is necessary to compensate transmission losses in order to deliver a sufficient quality of the signal of the device-under-test (in the following also mentioned as “DUT”). Transmission losses in general describe the accumulated decrease in intensity of a waveform energy as a wave propagates outwards from a source, or as it propagates through a certain area or through a certain type of structure.

In order to avoid or reduce transmission losses, different methods are known in the prior art. For example, a test head can be factory calibrated by the tester manufacturer before shipment. However, the DUT interface is usually created by the customers themselves and calibrated by measuring S-parameters of the signal path of the DUT interface. In this case, an expensive network analyzer and probing tools must be prepared by the customers.

It is therefore an object of the present invention to provide a system and a method for an easier calibration of a DUT interface, in particular without the need of an network analyzer.

The above object is solved by a system for calibrating a device-under-test interface according to claim 1 and a method for calibrating a device-under-test interface according to claim 13. Preferred embodiments of the invention are indicated by the subject-matter of the dependent claims.

Specifically, the present invention provides a system for calibrating a device-under-test interface, the system comprising:
a test head comprising a signal generator and a measuring unit, wherein the signal generator and the measuring unit are removably, directly and electrically connectable or connected to each other via a first signal line;
a DUT-unit comprising a loadboard, wherein the loadboard comprises an input port and an output port; wherein the input port and the output port are electrically connected with each other via a second signal line; and
a calculation unit.

The loadboard can be a printed circuit board (PCB) or other parts used in electrical and electronic engineering to connect electronic components to one another in a controlled manner. The measuring unit can be a digitizer.

The first signal line ensures that the cable ends of the test head are connected at the shortest possible distance.

The signal generator is configured to generate a first calibration signal and the system is configurable to transmit the first calibration signal to the measuring unit and to the input port. The first calibration signal can be a white noise or an impulse or a random phase modulation signal with a wide range of frequency components.

The measuring unit is configured to measure a second calibration signal based on the first calibration signal received from the signal generator; and measure a third calibration signal based on the first calibration signal received from the DUT-unit via the output port.

Further, the calculation unit is configured to calculate a main calibration signal based on the first, second and third calibration signal and further to calibrate the device under test interface based on the calculated main calibration signal.

The system mentioned above, ensures a calibration without a network analyzer, which is more cost-effective and much easier to apply, especially by costumers themselves. The calibration in general bases on the main calibration signal which bases on the first, second and third calibration signal. That means that the first calibration signal, generated by the signal generator, is transmitted to the measuring unit via the first signal line. The measuring unit then measures the second calibration signal based on the first calibration signal. Furthermore, the first calibration signal is transmitted to the input port of the DUT unit. Then, the third calibration signal is measured by the measuring unit, wherein the measuring unit receives the third calibration unit from the output port of the DUT unit.

In an embodiment, the second calibration signal is a signal with at least one modified signal parameter of the first calibration signal, wherein the at least one modified signal parameter is caused by transmission losses, for example of the first signal line. This embodiment enables a more detailed measurement and calibration of the DUT interface, because the mentioned transmission losses can be taken into account for the calibration.

In this context and in a further embodiment, the third calibration signal is a signal with at least one modified signal parameter of the first calibration signal, wherein the modified signal parameters are caused by transmission losses, for example of the second signal line.

In another embodiment, the at least one signal parameter is one of the frequency; the amplitude and the phase.

In a further preferred embodiment, the input port of DUT and the output port of DUT are directly connected with each other via the second signal line. This embodiment is therefore mentioned as “Short DUT”. The term “directly connected” means that no (active) electrical circuit is arranged between the input port and the output port. In other words, the “Short DUT” only comprises a transmission path—the second signal line, which directly connects the input and output port. The advantage is that with this embodiment the transmission losses can be determined exactly.

Moreover, in an embodiment, the DUT-unit comprises a device-under-test and wherein the input port is connected to the device-under-test via a first electrical connection and the output port is connected to the device-under-test via a second electrical connection.

In a preferred embodiment, the first electrical connection and the second electrical connection comprise the same length. This embodiment provides a symmetrically designed DUT interface, which ensures a more precise and better calibration.

In this context, preferably the length of the first signal line between the signal generator and the measuring unit of the test head is as short as possible. In addition, depending on the design of the DUT, also the length of the first and second electrical connection is as short as possible to also keep the transmission losses at a minimum.

Specifically, the present invention also provides a method for calibrating a device-under-test interface, the method comprising the following steps:
generating a first calibration signal by a signal generator of a test head and transmitting the first calibration signal to a measuring unit of the test head via a first signal line;
measuring a second calibration signal based on the first calibration signal by the measuring unit;
transmitting the first calibration signal to an input port of a DUT-unit;
measuring a third calibration signal based on the first calibration signal by the measuring unit at an output port of the DUT-unit;
calculating a main calibration signal based on the first, second and third calibration signal; and;
calibrate the device-under-test interface based on the calculated main calibration signal.

In a preferred embodiment, calculating the main calibration signal further comprises the step of:
calculating the Fourier Transformation Function of the first calibration signal, the second calibration signal and the third calibration signal by a calculation unit.

In a further embodiment, calculating the main calibration signal further comprises the step of:
calculating the Transfer Functions of the second calibration signal and the third calibration signal based on the first calibration signal by the calculation unit.

In this context, the aforementioned “S-parameter” and the term “Transfer Function” means the same.

Moreover, in an embodiment, calculating the main calibration signal further comprises the step of:
calculating the complex division of the calculated Transfer Functions of the second calibration signal and the third calibration signal.

Furthermore, calculating the main calibration signal further comprises the step of:
calculating the Complex Square Root of the calculated complex division of the second calibration signal and the third calibration signal.

In a further preferred embodiment, the Complex Square Root of the calculated complex division of the second calibration signal and the third calibration signal is calculated in each frequency bins.

Preferably, the Transfer Functions of the second calibration signal and the third calibration signal each based on the first calibration signal is done by the following equations:

$${T}_{SC} = \frac{{Y}_{SC}}{X}$$

$${T}_{di} = \frac{{Y}_{di}}{X}$$

wherein X is the calculated Fourier Transformation of the first calibration signal, Y_{SC} is the calculated Fourier Transformation of the second calibration signal and Y_{di} is the calculated Fourier Transformation of the third calibration signal.

The advantages and preferred embodiments listed with regard to the system are to be applied mutatis mutandis to the method and vice versa.

The above and further features and advantages of the invention will become more readily apparent from the following detailed description of preferred embodiments of the invention with reference to the accompanying drawings, in which like reference signs designate like features, and in which:

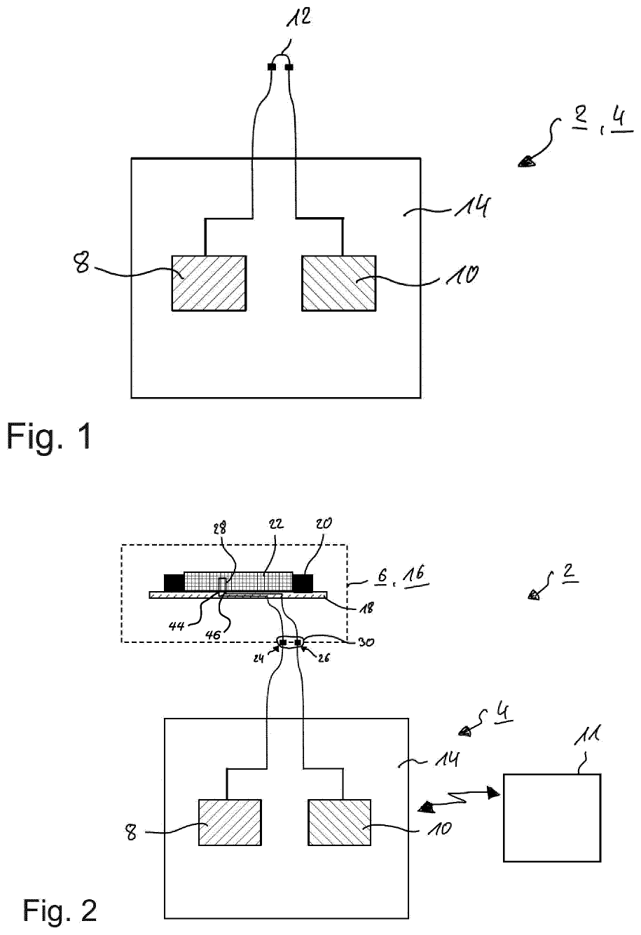

FIG. 1 shows a test head of a system for calibrating a device-under-test interface according to the invention;

FIG. 2 shows the test head according to FIG. 1 which is connected to a DUT-unit according to the invention;

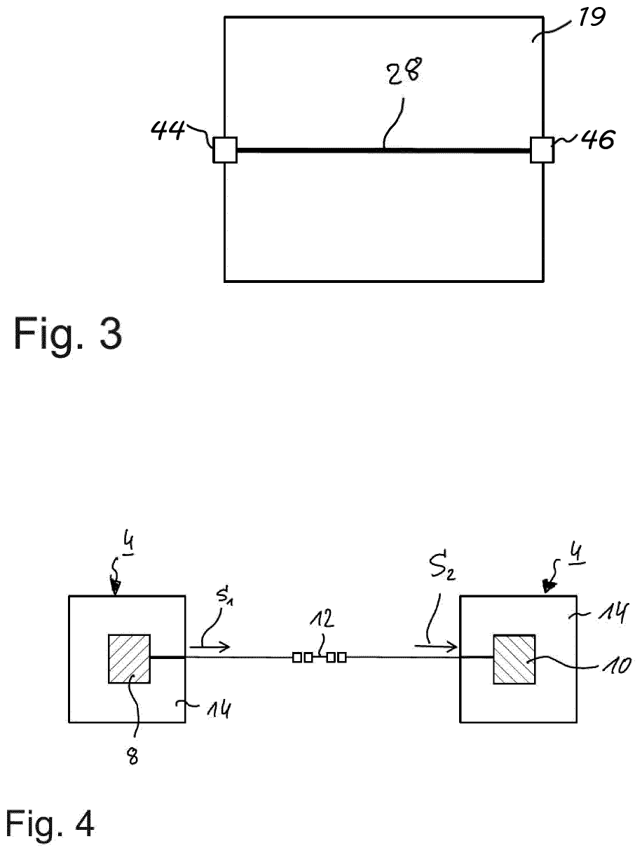

FIG. 3 shows a “Short DUT” according to the invention;

FIG. 4 shows a straight-line view of the electrical connection of the test head according to FIG. 1;

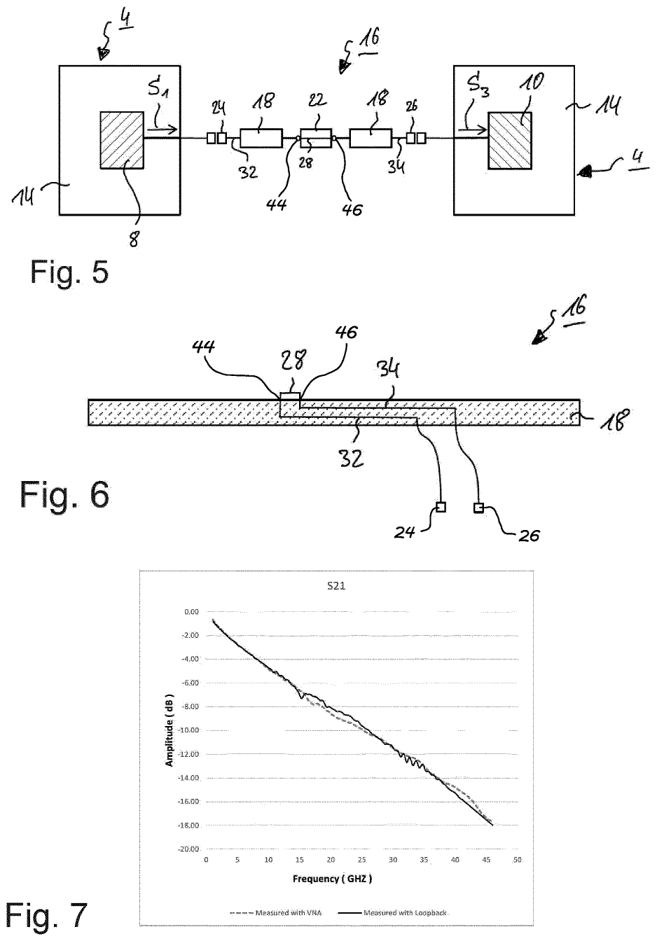

FIG. 5 shows a straight-line view of the electrical connection of the arrangement according to FIG. 2;

FIG. 6 shows an alternative embodiment of the DUT-unit; and

FIG. 7 shows a diagram in which a comparison between measurements using a network analyzer and the system and the method according to the invention.

FIG. 1 shows a test head 4 of a system 2 for calibrating a device-under-test interface 6 (see FIG. 2). The test head 4 comprises a signal generator 8 and a measuring unit 10, wherein the signal generator 8 and the measuring unit 10 are removably, directly and electrically connected to each other via a first signal line 12. The test head 4 further comprises a channel module 14 which carries the signal generator 8 and the measuring unit 10 as well as possible electrical lines to further connect the two components 8, 10 to each other via the first signal line 12. The first signal line 12 is also mentioned as “short cable” and preferably comprises a length which is as short as possible. In other words, the first signal line 12 ensure that the cable ends of the test head 4 are connected at the shortest possible distance.

FIG. 2 shows the test head 4 according to FIG. 1. The difference of the embodiment according to FIG. 2 is that the test head 4 is now electrically connected to a DUT-unit 16 (device-under-test unit). The DUT-unit 16 is a part of the device-under-test interface 6, wherein the device-under-test interface 6 can additionally comprise other parts, which are—by the way—not of interest to describe the system and the method according to the invention.

The DUT-unit 16 comprises a loadboard 18, a DUT-socket 20 and a device-under-test 22. The loadboard 18 comprises an input port 44 and an output port 46. The input port 44 and the output port 46 are electrically connected with each other via a second signal line 28, wherein the second signal line 28 is arranged in or on the loadboard 18 and in or on the device-under-test 22. Therefore and in other words, the device-under-test 22 can be understood as a calibration-device-under-test or as a “Short DUT” 19. Furthermore, the system 2 comprises a calculation unit 11, which is configured to communicate with the test head 4 and/or other parts of the system 2 and will be explained in more detail in the following.

To measure the necessary signals as will be described later, the signal generator 8 is connected to the input port 44 via an input port 24 and the measuring unit 10 is connected to the output port 46 via an output port 26 by means of electrical connectors 30, e.g. such as pogo pins.

In FIG. 3, the above-mentioned “Short DUT” 19 according to the invention is shown. As can be seen from FIG. 3, there are no active electrical circuits between the input port 44 and the output port 46. Instead, only the second signal line 28 connects the two ports 44, 46. In other words, there is only one transmission path, which directly connects the input port 44 and the output port 46.

FIG. 4 shows a straight-line view of the embodiment according to FIG. 1. In a first step of the calibration of the device-under-test interface 6, a first calibration signal S₁ is generated by the signal generator 8 and transmitted to the measuring unit 10 via the first signal line 12. The measuring unit 10 receives a second calibration signal S₂ based on the first calibration signal S₁. In other words, the measuring unit 10 receives a signal, the second calibration signal S₂, with at least one modified signal parameter of the first calibration signal S₁, wherein the at least one modified signal parameter is caused by transmission losses, for example of the first signal line 12. With this result, transmission losses can be taken into account regarding the calibration of the system 2.

In FIG. 5 the next step of the calibration process can be explained. FIG. 5 shows a straight-line view of the embodiment according to FIG. 2. The input port 24 is connected to the device-under-test 22 via a first electrical connection 32 and the output port 26 is connected to the device-under-test 22 via a second electrical connection 34

In this embodiment, the test head 4 is connected to the DUT-unit 16 and the first calibration signal S₁ is also transmitted through the DUT-unit 16 to the measuring unit 10. The measuring unit 10 then receives a third calibration signal S₃ based on the first calibration signal S₁. Compared to the step mentioned before, the measuring unit 10 receives a signal, the third calibration signal S₃, with at least one modified signal parameter of the first calibration signal S₁, wherein the at least one modified signal parameter is caused by transmission losses, for example of the second signal line 28. With this result, further transmission losses of the system 2 can be taken into account to calibrate it.

The calculation of the main calibration signal can mathematically be summarized as follows:

### Calculation 1

Execute FFT of each signal.

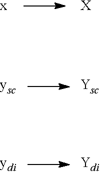

Wherein “x” is the first calibration signal S₁, “y_{sc}” is the second calibration signal S₂ and “y_{di}” is the third calibration signal S₃.

After that, calculation “2” will be executed by the calculation unit 11 as follows:

### Calculation 2

Calculate Transfer functions of each setups.

$${T}_{SC} = \frac{{Y}_{SC}}{X}$$

$${T}_{di} = \frac{{Y}_{di}}{X}$$

Wherein “T_{SC}” is the Transfer Function of the second calibration signal S₂ and “T_{di}” is the Transfer Function of the third calibration signal S₃.

In the next step, the complex division “T_{deembed}” of the Transfer Functions according to calculation “3”:

### Calculation 3

Calculate division of Tdi and Tsc in order to de-embed the signal path of test head.

$${T}_{deembed} = \frac{{T}_{di}}{{T}_{sc}}$$

The final step includes the calculation of the Complex Square Root “Tow” according to calculation “4”:

### Calculation 4

Calculate complex square root of T_{deembed} in each frequency bins. This yields transfer function of “one way” signal path of “DUT Interface”.

$${T}_{ow} = \sqrt{{T}_{deembed}}$$

It is noted that the above-mentioned calculation methods are for exemplary purpose and for the described embodiments of the system. Additionally or alternatively, other calculation methods can also be applied as long as they are mathematically equivalent.

As can be seen in FIG. 5, the design, especially regarding the length of the first and second electrical connection 32, 34, of the system is symmetrical. In an alternative embodiment the length of the first and second electrical connection 32, 34 is different and therefore asymmetrical. According to this alternative embodiment, the calculation of the main calibration signal differs also. Assuming that the length of the first electrical connection is “1” and the length of the second electrical connection is “α”, instead of calculation “4”, calculation “5” has to be applied:

### Calculation 5.

Instead of “Calculation 4”, calculate exponentiation of T_{deembed} in each frequency bins. This yields transfer function of one way signal path of “DUT Interface”.

$${T}_{owTx} = {( {T}_{deembed} )}^{\frac{1}{1 + α}}$$

$${T}_{owRx} = {( {T}_{deembed} )}^{\frac{α}{1 + α}}$$

Calculations “5” and “4” are equivalent, if 1=a. In this case, the electrical connections are symmetric and comprise the same length as shown in the embodiment of FIG. 5.

FIG. 6 shows an alternative embodiment of the DUT-unit 16. In this embodiment, no DUT socket 20 and no device-under-test 22 is provided. Hence, this much easier designed DUT-unit 16 is called “shorted loadboard”.

FIG. 7 shows graphs of two different measurements in comparison. One measurement was made conventionally by using a network analyzer. The other measurement was made according to the inventive system and method. As can be taken from the graphs only a small difference can be seen in the two curves. However, this difference is not from a practical importance.

The invention is not limited to the embodiments described above. Rather, other variants of the invention can also be derived therefrom by the person skilled in the art without leaving the object of the invention. Furthermore, in particular, all individual features described in connection with the embodiment examples can also be combined with each other in other ways without leaving the object of the invention.

### LIST OF REFERENCE NUMERALS

2 system
4 test head
6 device-under-test interface
8 signal generator
10 measuring unit
11 calculation unit
12 first signal line
14 channel module
16 DUT-unit
18 loadboard
19 Short DUT
20 DUT-socket
22 device-under-test
24 input port
26 output port
28 second signal line
30 electrical connectors
32 first electrical connection
34 second electrical connection
44 input port of DUT
46 output port of DUT
S₁ first calibration signal
S₂ second calibration signal
S₃ third calibration signal

1. A system for calibrating a device-under-test interface, the system comprising:
a test head comprising a signal generator and a measuring unit, wherein the signal generator and the measuring unit are configured to be connected to each other via a first signal line;
a DUT-unit comprising a loadboard, wherein the loadboard comprises an input port and an output port, and wherein the input port and the output port are electrically connected with each other via a second signal line; and
a calculation unit;
wherein
the signal generator is configured to:
generate a first calibration signal; and
transmit the first calibration signal to the measuring unit and to the input port;
the measuring unit is configured to:
measure a second calibration signal based on the first calibration signal received from the signal generator; and
measure a third calibration signal based on the first calibration signal received from the DUT-unit via the output port; and
the calculation unit is configured to:
calculate a main calibration signal based on the first, second, and third calibration signals, and
calibrate the DUT interface based on the main calibration signal.

2. The system according to claim 1, wherein the second calibration signal differs from the first calibration signal by at least one modified signal parameter caused by transmission losses.

3. The system according to claim 1, wherein the third calibration signal differs from the first calibration signal by at least one modified signal parameter caused by transmission losses.

4. The system according to claim 3, wherein the at least one modified signal parameter is one of:
frequency;
amplitude; or
phase.

5. The system according to claim 1, wherein, to calculate the main calibration signal, the calculation unit is configured to calculate a Fourier Transformation of each of the first calibration signal, the second calibration signal, and the third calibration signal.

6. The system according to claim 1, wherein, to calculate the main calibration signal, the calculation unit is further configured to calculate a first transfer function of the second calibration signal relative to the first calibration signal and a second transfer function of the third calibration signal relative to the first calibration signal.

7. The system according to claim 6, wherein, to calculate the main calibration signal, the calculation unit is further configured to calculate a complex division of the first transfer function divided by the second transfer function.

8. The system according to claim 7, wherein, to calculate the main calibration signal, the calculation unit is further configured to calculate a complex square root of the complex division of the first transfer function divided by the second transfer function.

9. The system according to claim 8, wherein the calculation unit is configured to calibrate the DUT interface device based on the complex square root.

10. The system according to claim 1, wherein the input port and the output port are directly connected with each other via the second signal line.

11. The system according to claim 1, wherein the DUT-unit comprises:
a DUT,
a second input port is connected to the DUT via a first electrical connection, and
a second output port is connected to the DUT via a second electrical connection.

12. The system according to claim 11, wherein the first electrical connection and the second electrical connection have a same length.

13. A method for calibrating a device-under-test (DUT) interface, the method comprising:
generating, by a signal generator of a test head, a first calibration signal;
transmitting, by the signal generator, the first calibration signal to a measuring unit of the test head via a first signal line;
measuring, by the measuring unit, a second calibration signal based on the first calibration signal received from the signal generator 10);
transmitting, by the signal generator, the first calibration signal to an input port of a DUT-unit;
measuring, by the measuring unit, a third calibration signal based on the first calibration signal received by the measuring unit from an output port of the DUT-unit;
calculating, by a calculation unit, a main calibration signal based on the first, second, and third calibration signals; and;
calibrating, by the calculation unit, the DUT interface based on the main calibration signal.

14. The method according to claim 13, wherein calculating the main calibration signal further comprises:
calculating a Fourier Transformation of each of the first calibration signal, the second calibration signal, and the third calibration signal 11).

15. The method according to claim 14, wherein calculating the main calibration signal further comprises:
calculating a first transfer function of the second calibration signal relative to the first calibration signal and a second transfer function of the third calibration signal each based on relative to the first calibration signal.

16. The method according to claim 15, wherein calculating the main calibration signal further comprises:
calculating a complex division of the first transfer function divided by the second transfer function.

17. The method according to claim 16, wherein calculating the main calibration signal further comprises:
calculating a complex square root of the complex division of the first transfer function divided by the second transfer function.

18. The method according to claim 15, further comprising:
calculating a complex square root of a complex division of the first transfer function divided by the second transfer function in each of a plurality of frequency bins.

19. The method according to claim 15, wherein;
the first transfer function is calculated according to
$${T}_{SC} = \frac{{Y}_{SC}}{X}$$
wherein X is the Fourier Transformation of the first calibration signal and Y_{SC} is the Fourier Transformation of the second calibration signal; and.
the second transfer function is calculated according to:
Y_{di}/X
wherein X is the Fourier Transformation of the first calibration signal and Y_{di} is the Fourier Transformation of the third calibration signal.

20. The method according to claim 13, wherein the first calibration signal comprises at least one of white noise, an impulse, or a random phase modulation signal.
